(19) United States
(12) Patent Application Publication
(10) Pub. No.: US 2015/0179749 A1
(43) Pub. Date: Jun. 25, 2015

(54) Non-volatile Memory Cell With Self Aligned Floating And Erase Gates, And Method Of Making Same

(71) Applicant: Silicon Storage Technology, Inc, San Jose, CA (US)

(72) Inventors: Bomy Chen, Cupertino, CA (US); Chien-Sheng Su, Saratoga, CA (US); Nhan Do, Saratoga, CA (US)

(73) Assignee: Silicon Storage Technology, Inc, San Jose, CA (US)

(21) Appl. No.: 14/133,821

(22) Filed: Dec. 19, 2013

(51) Int. Cl. H01L 29/423; H01L 29/66; G11C 16/10; H01L 29/788; H01L 27/115

(52) U.S. Cl. CPC H01L 29/42328; H01L 29/7889; H01L 27/11517; G11C 16/10; H01L 29/66825

(57) ABSTRACT

A memory device, and method of making the same, in which a trench is formed into a substrate of semiconductor material. The source region is formed under the trench, and the channel region between the source and drain regions includes a first portion that extends substantially along a sidewall of the trench and a second portion that extends substantially along the surface of the substrate. The floating gate is disposed in the trench, and is insulated from the channel region first portion for controlling its conductivity. The control gate is disposed over and insulated from the channel region second portion, for controlling its conductivity. The erase gate is disposed at least partially over and insulated from the floating gate. Any portion of the trench between the pair of floating gates is free of electrically conductive elements except for a lower portion of the erase gate.

### TECHNICAL FIELD

The present invention relates to a self-aligned method of forming a semiconductor memory array of floating gate memory cells. The present invention also relates to a semiconductor memory array of floating gate memory cells of the foregoing type.

### BACKGROUND OF THE INVENTION

Non-volatile semiconductor memory cells using a floating gate to store charges thereon and memory arrays of such non-volatile memory cells formed in a semiconductor substrate are well known in the art. Typically, such floating gate memory cells have been of the split gate type, or stacked gate type.

One of the problems facing the manufacturability of semiconductor floating gate memory cell arrays has been the alignment of the various components such as source, drain, control gate, and floating gate. As the design rule of integration of semiconductor processing decreases, reducing the smallest lithographic feature, the need for precise alignment becomes more critical. Alignment of various parts also determines the yield of the manufacturing of the semiconductor products.

Self-alignment is well known in the art. Self-alignment refers to the act of processing one or more steps involving one or more materials such that the features are automatically aligned with respect to one another in that step processing. Accordingly, the present invention uses the technique of self-alignment to achieve the manufacturing of a semiconductor memory array of the floating gate memory cell type.

There is a constant need to shrink the size of the memory cell arrays in order to maximize the number of memory cells on a single wafer, while not sacrificing performance (i.e. program, erase and read efficiencies and reliabilities). It is well known that forming memory cells in pairs, with each pair sharing a single source region, and with adjacent pairs of cells sharing a common drain region, reduces the size of the memory cell array. It is also known to form trenches into the substrate, and locate one or more memory cell elements in the trench to increase the number of memory cells that fit into a given unit surface area (see for example U.S. Pat. Nos. 5,780,341 and 6,891,220). However, such memory cells use the control gate to both control the channel region (in a low voltage operation) and to erase the floating gate (in a high voltage operation). This means the control gate is both a low voltage and high voltage element, making it difficult to surround it with sufficient insulation for high voltage operation while not being too electrically isolated for low voltage operation. Moreover, the proximity of the control gate to the floating gate needed for an erase operation can result in unwanted levels of capacitive coupling between the control gate and the floating gate.

U.S. Pat. No. 8,148,768 discloses forming one or more memory elements in a substrate trench, and provides a separate erase gate for memory cell erase, relieving the control gate from any high voltage erase operation. The memory cell array includes poly blocks 50 in electrical contact with the source regions 46, whereby the poly blocks 50 are formed continuously across the isolation regions to adjacent active regions, thus forming source lines each of which are electrically connected together all the source regions for each row of paired memory cells. The poly blocks 50 extend up parallel to the floating gates, for better capacitive coupling there between. However, a separate polysilicon formation step is needed just to form poly blocks 50, which significantly increases the cost of production. It also requires an extra electrical contact at the end of each row of poly blocks 50.

Thus it is an object of the present invention to create a memory cell configuration and method of manufacture where the memory cell elements are self aligned to each other, and that improved programming, erase and read efficiencies are achieved without excessive manufacturing cost.

### SUMMARY OF THE INVENTION

The aforementioned problems, needs and objects are addressed by the memory devices and methods disclosed herein. Specifically, a pair of memory cells includes a substrate of semiconductor material having a first conductivity type and a surface, a trench formed into the surface of the substrate and including a pair of opposing sidewalls, a first region formed in the substrate under the trench, a pair of second regions formed in the substrate, with a pair of channel regions each in the substrate between the first region and one of the second regions, wherein the first and second regions have a second conductivity type, and wherein each of the channel regions includes a first portion that extends substantially along one of the opposing trench sidewalls and a second portion that extends substantially along the substrate surface, a pair of electrically conductive floating gates each at least partially disposed in the trench adjacent to and insulated from one of the channel region first portions for controlling a conductivity of the one channel region first portion, an electrically conductive erase gate having a lower portion disposed in the trench and disposed adjacent to and insulated from the floating gates, and a pair of electrically conductive control gates each disposed over and insulated from one of the channel region second portions for controlling a conductivity of the one channel region second portion, wherein any portion of the trench between the pair of floating gates is free of electrically conductive elements except for the erase gate lower portion.

A method of forming a pair of memory cells includes forming a trench into a surface of the semiconductor substrate of first conductivity type, wherein the trench has a pair of opposing sidewalls, forming a first region in the substrate and under the trench, forming a pair of second regions in the substrate, with a pair of channel regions each defined in the substrate between the first region and one of the second regions, wherein the first and second regions have a second conductivity type, and wherein each of the channel regions includes a first portion that extends substantially along one of the opposing trench sidewalls and a second portion that extends substantially along the surface of the substrate, forming a pair of electrically conductive floating gates each at least partially disposed in the trench adjacent to and insulated from one of the channel region first portions for controlling a conductivity of the one channel region first portion, forming an electrically conductive erase gate having a lower portion disposed in the trench and disposed adjacent to and insulated from the floating gates, and forming a pair of electrically conductive control gates each disposed over and insulated from one of the channel region second portions for controlling a conductivity of the one channel region second portion, wherein any portion of the trench between the pair of floating gates is free of electrically conductive elements except for the erase gate lower portion.

A method of programming one of a pair of memory cells, where the pair of memory cells comprise a substrate of semiconductor material having a first conductivity type and a surface, a trench formed into the surface of the substrate and including a pair of opposing sidewalls, a first region formed in the substrate under the trench, a pair of second regions formed in the substrate, with a pair of channel regions each in the substrate between the first region and one of the second regions, wherein the first and second regions have a second conductivity type, and wherein each of the channel regions includes a first portion that extends substantially along one of the opposing trench sidewalls and a second portion that extends substantially along the substrate surface, a pair of electrically conductive floating gates each at least partially disposed in the trench adjacent to and insulated from one of the channel region first portions for controlling a conductivity of the one channel region first portion, an electrically conductive erase gate having a lower portion disposed in the trench and disposed adjacent to and insulated from the floating gates, and a pair of electrically conductive control gates each disposed over and insulated from one of the channel region second portions for controlling a conductivity of the one channel region second portion, wherein any portion of the trench between the pair of floating gates is free of electrically conductive elements except for the erase gate lower portion. The method including applying a positive voltage to one of the second regions, applying a positive voltage to one of the control gates, applying a high positive voltage to the first region, and applying a high positive voltage to the erase gate.

Other objects and features of the present invention will become apparent by a review of the specification, claims and appended figures.

### BRIEF DESCRIPTION OF THE DRAWINGS

FIG. 1A is a top view of a semiconductor substrate used in the first step of the method of present invention to form isolation regions.

FIG. 1B is a cross sectional view of the structure taken along the line 1B-1B showing the initial processing steps of the present invention.

FIG. 1C is a top view of the structure showing the next step in the processing of the structure of FIG. 1B, in which isolation regions are defined.

FIG. 1D is a cross sectional view of the structure in FIG. 1C taken along the line 1D-1D showing the isolation trenches formed in the structure.

FIG. 1E is a cross sectional view of the structure in FIG. 1D showing the formation of isolation blocks of material in the isolation trenches.

FIG. 1F is a cross sectional view of the structure in FIG. 1E showing the final structure of the isolation regions.

FIGS. 2A-2H are cross sectional views of the semiconductor structure in FIG. 1F taken along the line 2A-2A showing in sequence the steps in the processing of the semiconductor structure in the formation of a non-volatile memory array of floating gate memory cells of the present invention.

### DETAILED DESCRIPTION OF THE PREFERRED EMBODIMENTS

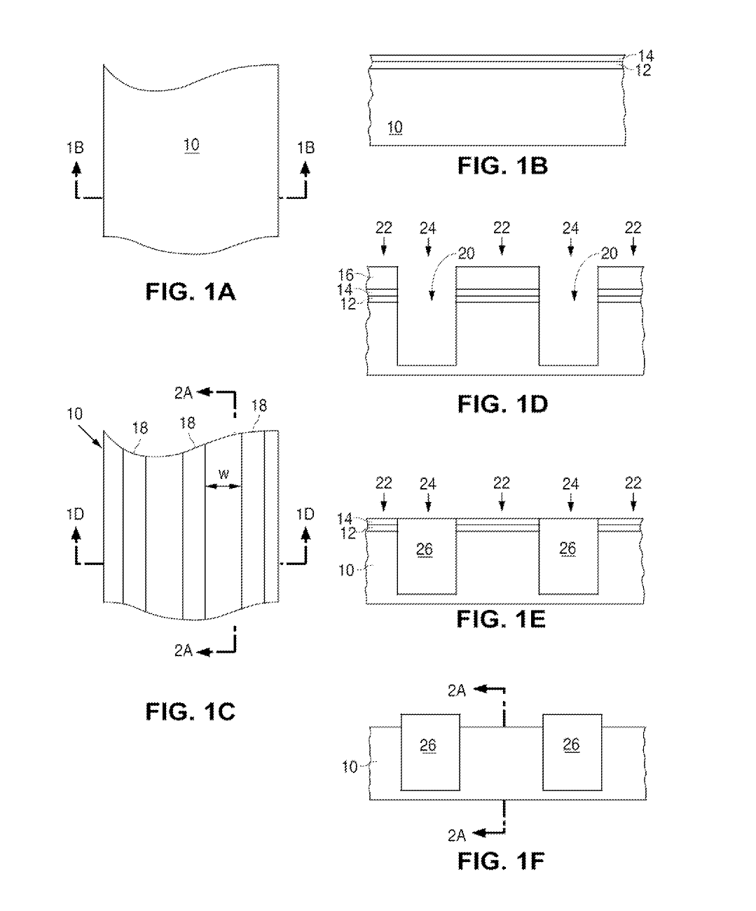

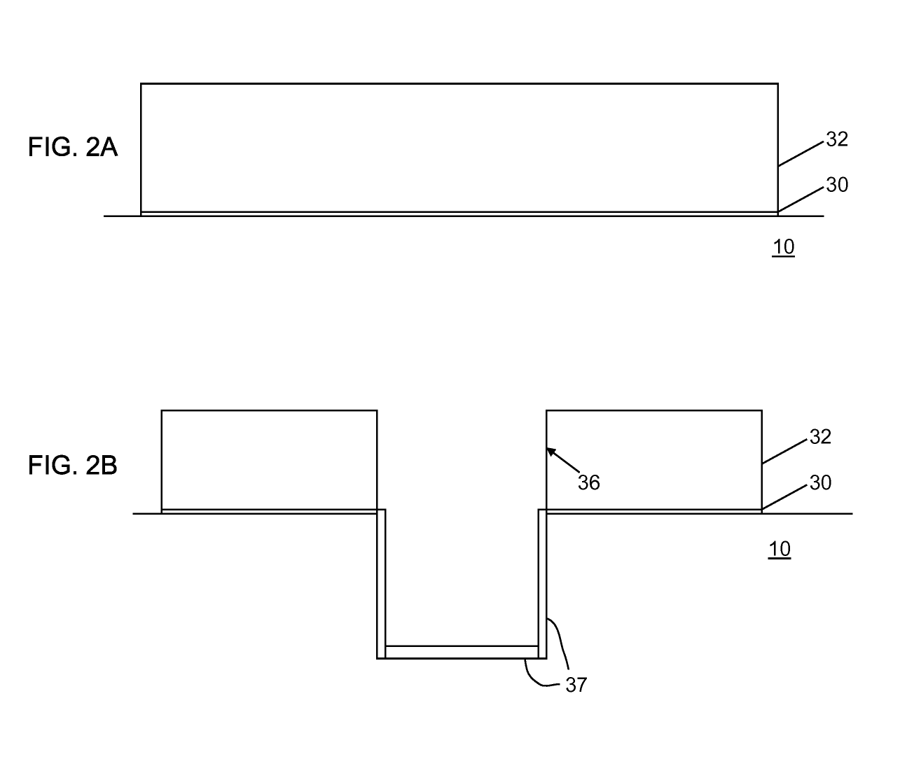

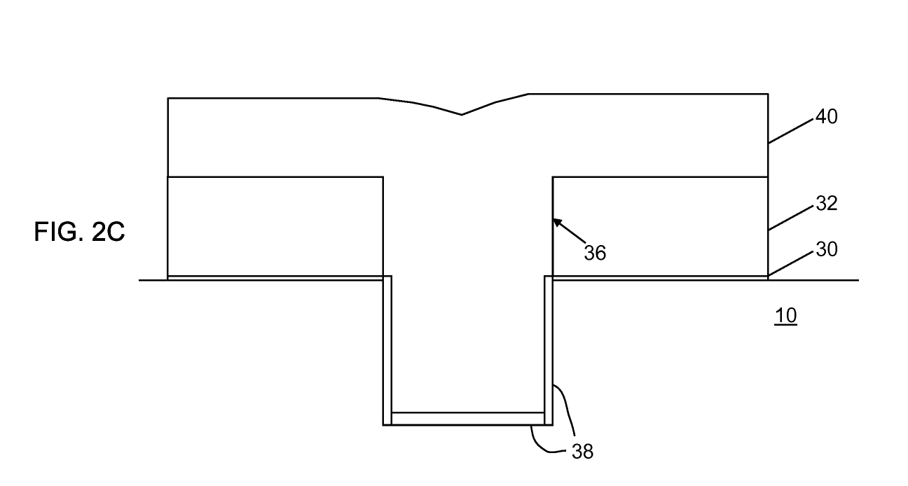

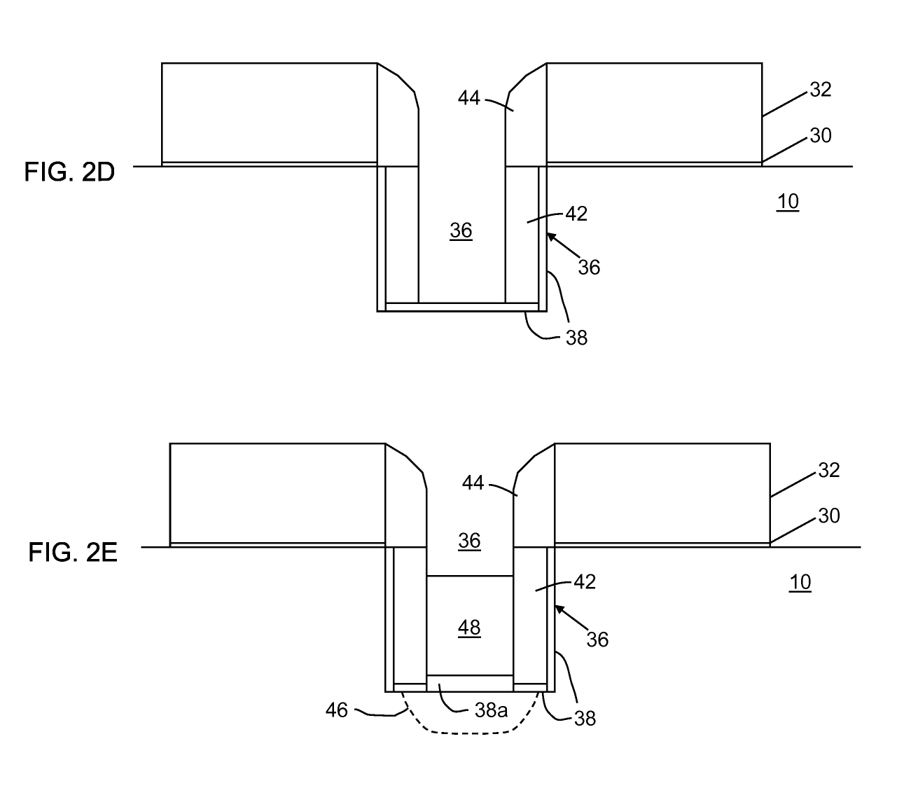

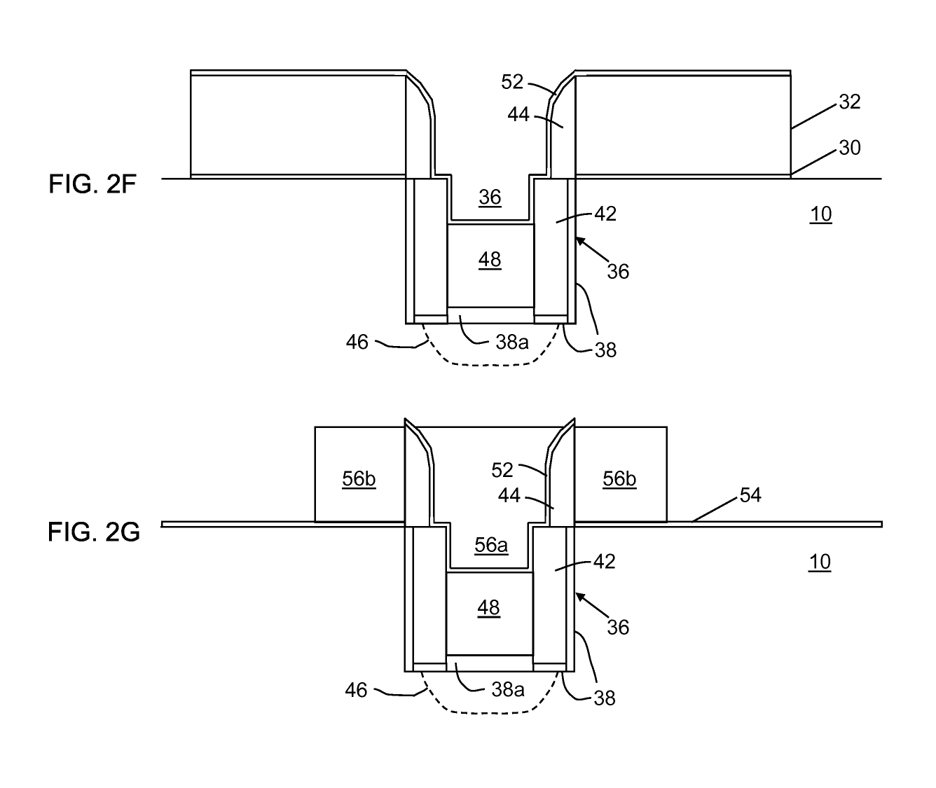

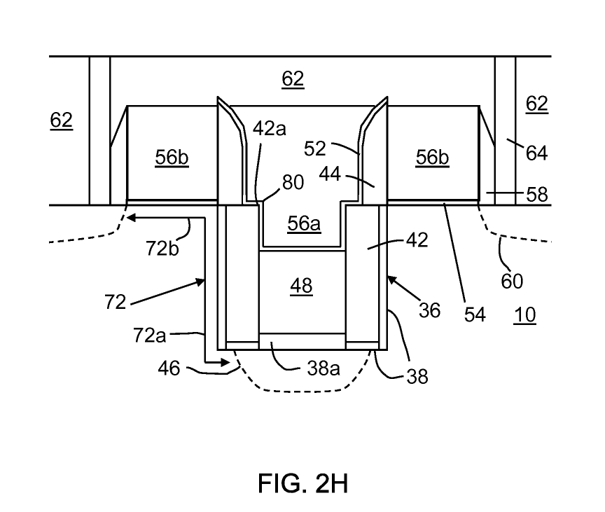

The method of the present invention is illustrated in FIGS. 1A to 1F and 2A to 2F (which show the processing steps in making the memory cell array of the present invention). The method begins with a semiconductor substrate 10, which is preferably of P type and is well known in the art. The thicknesses of the layers described below will depend upon the design rules and the process technology generation. What is described herein is for deep sub-micron technology process. However, it will be understood by those skilled in the art that the present invention is not limited to any specific process technology generation, nor to any specific value in any of the process parameters described hereinafter.

Isolation Region Formation

FIGS. 1A to 1F illustrate the well known STI method of forming isolation regions on a substrate. Referring to FIG. 1A there is shown a top plan view of a semiconductor substrate 10 (or a semiconductor well), which is preferably of P type and is well known in the art. First and second layers of material 12 and 14 are formed (e.g. grown or deposited) on the substrate. For example, first layer 12 can be silicon dioxide (hereinafter “oxide”), which is formed on the substrate 10 by any well known technique such as oxidation or oxide deposition (e.g. chemical vapor deposition or CVD) to a thickness of approximately 50-150 Å. Nitrogen doped oxide or other insulation dielectrics can also be used. Second layer 14 can be silicon nitride (hereinafter “nitride”), which is formed over oxide layer 12 preferably by CVD or PECVD to a thickness of approximately 1000-5000 Å. FIG. 1B illustrates a cross-section of the resulting structure.

Once the first and second layers 12/14 have been formed, suitable photo resist material 16 is applied on the nitride layer 14 and a masking step is performed to selectively remove the photo resist material from certain regions (stripes 18) that extend in the Y or column direction, as shown in FIG. 1C. Where the photo-resist material 16 is removed, the exposed nitride layer 14 and oxide layer 12 are etched away in stripes 18 using standard etching techniques (i.e. anisotropic nitride and oxide/dielectric etch processes) to form trenches 20 in the structure. The distance W between adjacent stripes 18 can be as small as the smallest lithographic feature of the process used. A silicon etch process is then used to extend trenches 20 down into the silicon substrate 10 (e.g. to a depth of approximately 500 Å to several microns), as shown in FIG. 1D. Where the photo resist 16 is not removed, the nitride layer 14 and oxide layer 12 are maintained. The resulting structure illustrated in FIG. 1D now defines active regions 22 interlaced with isolation regions 24.

The structure is further processed to remove the remaining photo resist 16. Then, an isolation material such as silicon dioxide is formed in trenches 20 by depositing a thick oxide layer, followed by a Chemical-Mechanical-Polishing or CMP etch (using nitride layer 14 as an etch stop) to remove the oxide layer except for oxide blocks 26 in trenches 20, as shown in FIG. 1E. The remaining nitride and oxide layers 14/12 are then removed using nitride/oxide etch processes, leaving STI oxide blocks 26 extending along isolation regions 24, as shown in FIG. 1F.

The STI isolation method described above is the preferred method of forming isolation regions 24. However, the well known LOCOS isolation method (e.g. recessed LOCOS, poly buffered LOCOS, etc.) could alternately be used, where the trenches 20 may not extend into the substrate, and isolation material may be formed on the substrate surface in stripe regions 18. FIGS. 1A to 1F illustrate the memory cell array region of the substrate, in which columns of memory cells will be formed in the active regions 22 which are separated by the isolation regions 24. It should be noted that the substrate 10 also includes at least one periphery region (not shown) in which control circuitry is formed that will be used to operate the memory cells formed in the memory cell array region. Preferably, isolation blocks 26 are also formed in the periphery region during the same STI or LOCOS process described above.

Memory Cell Formation

The structure shown in FIG. 1F is further processed as follows. FIGS. 2A to 2H show the cross sections of the structure in the active regions 22 from a view orthogonal to that of FIG. 1F (along line 2A-2A as shown in FIGS. 1C and 1F), as the next steps in the process of the present invention are performed concurrently in both regions.

An insulation layer 30 (preferably oxide or nitrogen doped oxide) is first formed over the substrate 10 (e.g. ˜10 to 50 Å thick). The active region portions of the substrate 10 can be doped at this time for better independent control of the cell array portion of the memory device relative to the periphery region. Such doping is often referred to as a Vₜ implant or cell well implant, and is well known in the art. During this implant, the periphery region is protected by a photo resist layer, which is deposited over the entire structure and removed from just the memory cell array region of the substrate. Next, a thick layer of hard mask material 32 such as nitride is formed over oxide layer 30 (e.g. ˜3500 Å thick). The resulting structure is shown in FIG. 2A.

A plurality of parallel second trenches 36 are formed in the nitride and oxide layers 32, 30 by applying a photo resist (masking) material on the nitride layer 32, and then performing a masking step to remove the photo resist material from selected parallel stripe regions. Anisotropic nitride and oxide etches are used to remove the exposed portions of nitride and oxide layers 32, 30 in the stripe regions, leaving second trenches 36 that extend down to and expose substrate 10. A silicon anisotropic etch process is then used to extend second trenches 36 down into the substrate 10 in each of the active regions 22 (for example, down to a depth of approximately one feature size deep, e.g. about 500 Å to several microns). The photo resist can be removed before or after trenches 36 are formed into the substrate 10.

A sacrificial layer of insulation material 37 is next formed (preferably using a thermal oxidation or CVD oxide process) along the exposed silicon in second trenches 36 that forms the bottom wall and lower sidewalls of the second trenches 36. The formation of oxide 37 allows for the removal of damaged silicon by the oxidation step followed by oxide removal. An implant step is next performed to implant dopant in the substrate underneath trenches 36 (i.e. those portions of the substrate that will be underneath the floating gates to adjust the floating gate VT and/or prevent punch-though). Preferably, the implant is an angled implant. The resulting structure is shown FIG. 2B.

An oxide etch is performed to remove sacrificial oxide layer 37. A layer of oxide 38 is then formed (preferably using a thermal oxidation or CVD oxide process) along the exposed silicon in second trenches 36 that forms the bottom wall and lower sidewalls of the second trenches 36 (e.g. ˜60 Å to 150 Å thick). A thick layer of polysilicon 40 (hereinafter “poly”) is then formed over the structure, which fills second trenches 36. Poly layer 40 can be doped (e.g. n+) by ion implant, or by an in-situ phosphorus or arsenic doped poly process. An implant anneal process can be performed if the poly 40 is doped by ion implant. The resulting structure is shown in FIG. 2C.

A poly etch process (e.g. a CMP process using nitride layer 32 as an etch stop) is used to remove poly layer 40 except for blocks of the polysilicon layer 40 left remaining in second trenches 36. A controlled poly etch is then used to lower the height of poly blocks, where the tops of poly blocks are disposed approximately even with the surface of substrate 10. Oxide spacers 44 are then formed along the sidewalls of the second trenches 36. Formation of spacers is well known in the art, and involves the deposition of a material over the contour of a structure, followed by an anisotropic etch process, whereby the material is removed from horizontal surfaces of the structure, while the material remains largely intact on vertically oriented surfaces of the structure (with a rounded upper surface). Spacers 44 are formed by depositing oxide over the structure (e.g. approximately 300 to 1000 Å thickness) followed by an anisotropic oxide etch, which results in spacers 44 along the trench sidewalls, and partially covering the poly block. An anisotropic poly etch is then used to remove that exposed portion of the poly block, leaving a pair of poly blocks 42 each located under (and self-aligned to) one of the spacers 44. The resulting structure is shown in FIG. 2D.

Suitable ion implantation that, depending upon if the substrate is P or N type, may include arsenic, phosphorous, boron and/or antimony (and optional anneal), is then made across the surface of the structure to form first (source) regions 46 in the substrate portions at the bottom of second trenches 36, followed by an anneal of the implant. The source regions 46 are self-aligned to the second trenches 36, and have a second conductivity type (e.g. N type) that is different from a first conductivity type of the substrate (e.g. P type). In order to get the source regions 46 to extend across the isolation regions 24, the ion implant is a deep implant or the STI insulation material is removed from the isolation region portions of the second trenches 36 before the implantation. An oxidation process is next performed to thicken the portion 38a of the oxide layer 38 between poly blocks 42 at the bottom of second trenches 36. This oxidation process helps spread the dopant forming the source region 46 more evenly underneath the floating gates, and it smooths the bottom corners of the floating gates. A thick oxide layer is then formed over the structure, followed by an anisotropic oxide etch which removes that oxide layer except for oxide blocks 48 at the bottom of second trenches 36. The resulting structure is shown in FIG. 2E.

An isotropic oxide etch is then performed, to reduce the thickness of oxide spacers 44 (which also slightly reduces the height of oxide blocks 48). An oxide deposition process is performed to form oxide layer 52 over the structure including in trenches 36. Layer 52 can be formed using a high quality oxide chemical vapor deposition (CVD) process. The resulting structure is shown in FIG. 2F. Alternately, oxide layer 52 can be formed using a high-temperature thermal oxidation (HTO) process, which means layer 52 would only be formed on exposed portions of poly blocks 42.

Oxide and nitride etches are performed to remove oxide 52 on nitride 32, to remove nitride 32, and remove oxide 30. An optional lithographic process can be performed to preserve oxide 52 in trenches 36 (as shown in FIG. 2G). Alternately, nitride 32 can be removed before the formation of oxide 52. A P-Type ion implantation is used to form the control (or WL) transistor for the memory cell. A thermal oxidation is performed to form a gate oxide layer 54 on the exposed portions of substrate 10 (to a thickness of 15 Å˜70 Å). A thick poly layer is deposited over the structure (i.e. on oxide layer 54 and in trench 36). In-situ phosphorus or arsenic doping can be performed, or alternately a poly implant and anneal process can be used. A poly planarization etch is performed to planarize the top of the poly layer. A photolithography and poly etch process is used to remove portions of the poly layer, leaving poly block 56a in trench 36 and poly blocks 56b on gate oxide layer 54 outside of trench 36 and adjacent oxide spacers 44, as illustrated in FIG. 2G.

An oxide etch is then used to remove the exposed portions of oxide layer 54. An oxide deposition and anisotropic etch are used to form oxide spacers 58 on the outer sides of poly blocks 56b. Suitable ion implantation (and anneal) is used to form second (drain) regions 60 in the substrate.

Insulation material 62, such as BPSG or oxide, is then formed over the entire structure. A masking step is performed to define etching areas over the drain regions 60. The insulation material 62 is selectively etched in the masked regions to create contact openings that extend down to drain regions 60. The contact openings are then filled with a conductor metal (e.g. tungsten) to form metal contacts 64 that are electrically connected to drain regions 60. The final active region memory cell structure is illustrated in FIG. 2H.

As shown in FIG. 2H, the process of the present invention forms pairs of memory cells that mirror each other, with a memory cell formed on each side of the oxide block 48. For each memory cell, first and second regions 46/60 form the source and drain regions respectively (although those skilled in the art know that source and drain can be switched during operation). Poly block 42 constitutes the floating gate, poly block 56b constitutes the control gate, and poly block 56a constitutes the erase gate. Channel regions 72 for each memory cell are defined in the surface portions of the substrate that is in-between the source and drain 46/60. Each channel region 72 includes two portions joined together at an approximate right angle, with a first (vertical) portion 72a extending along the vertical wall of filled second trench 36 and a second (horizontal) portion 72b extending between the sidewall of filled second trench 36 and the drain region 60. Each pair of memory cells share a common source region 46 that is disposed under filled second trench 36 (and under floating gates 42). Similarly, each drain region 60 is shared between adjacent memory cells from different mirror sets of memory cells. In the array of the memory cells shown in FIG. 2H, control gates 56b are continuously formed as control (word) lines that extend across both the active and isolation regions 22/24.

The floating gates 42 are disposed in second trenches 36, with each floating gate facing and insulated from one of the channel region vertical portions 72a, and over one of the source regions 46. Each floating gate 42 includes an upper portion that has a corner edge 42a that faces (and is insulated from) a notch 80 of erase gate 56a, thus providing a path for Fowler-Nordheim tunneling through oxide layer 52 to erase gate 56a.

Memory Cell Operation

The operation of the memory cells will now be described. The operation and the theory of operation of such memory cells are also described in U.S. Pat. No. 5,572,054, whose disclosure is incorporated herein by reference with regard to the operation and theory of operation of a non-volatile memory cell having a floating gate, gate to gate tunneling, and an array of memory cells formed thereby.

To erase a selected memory cell in any given active region 22, a ground potential is applied to both its source region 46 and its word line (control gate 56b). A high-positive voltage (e.g. +11.5 volts) is applied to its erase gate 56a. Electrons on the floating gate 42 are induced through the Fowler-Nordheim tunneling mechanism to tunnel from the corner edge 42a of floating gate 42, through the oxide layer 52, and onto the erase gate 56b, leaving the floating gate 42 positively charged. Tunneling is enhanced by the sharpness of corner edge 42a, and the fact that edge 42a faces a notch 80 formed in the erase gate 56a. The notch 80 results from the erase gate 56a having a lower portion that is narrower in width than its upper portion, and that it extends into the top portion of second trench 36 so as to wrap around corner edge 42a. It should be noted that since each erase gate 56a faces a pair of floating gates 42, both floating gates 42 in each pair will be erased at the same time.

When a selected memory cell is desired to be programmed, a small voltage (e.g. 0.5 to 2.0 V) is applied to its drain region 60. A positive voltage level in the vicinity of the threshold voltage of the MOS structure (on the order of approximately +0.2 to 1 volt above the drain 60, such as 1 V) is applied to its control gate 56b. A positive high voltage (e.g. on the order of 5 to 10 volts, such as 6 V) is applied to its source region 46 and erase gate 56a. Because the floating gate 42 is highly capacitively coupled to the source region 46 and erase gate 56a, the floating gate 42 “sees” a voltage potential of on the order of +4 to +8 volts. Electrons generated by the drain region 60 will flow from that region towards the source region 46 through the deeply depleted horizontal portion 72b of the channel region 72. As the electrons reach the vertical portion 72a of the channel region 72, they will see the high potential of floating gate 42 (because the floating gate 42 is strongly voltage-coupled to the positively charged source region 46 and erase gate 56a). The electrons will accelerate and become heated, with most of them being injected into and through the insulating layer 36 and onto the floating gate 42, thus negatively charging the floating gate 42. Low or ground potential is applied to the source/drain regions 46/60 and control gates 56b for memory cell rows/columns not containing the selected memory cell. Thus, only the memory cell in the selected row and column is programmed.

The injection of electrons onto the floating gate 42 will continue until the reduction of the charge on the floating gate 42 can no longer sustain a high surface potential along the vertical channel region portion 72a to generate hot electrons. At that point, the electrons or the negative charges in the floating gate 42 will decrease the electron flow from the drain region 60 onto the floating gate 42.

Finally, to read a selected memory cell, ground potential is applied to its source region 46. A read voltage (e.g. ˜0.6 to 1 volt) is applied to its drain region 60, and a Vcc voltage of approximately 1 to 4 volts (depending upon the power supply voltage of the device) is applied to its control gate 56b. If the floating gate 42 is positively charged (i.e. the floating gate is discharged of electrons), then the vertical channel region portion 72a (adjacent to the floating gate 42) is turned on. When the control gate 56b is raised to the read potential, the horizontal channel region portion 72b (adjacent the control gate 56b) is also turned on. Thus, the entire channel region 72 will be turned on, causing electrons to flow from the source region 46 to the drain region 60. This sensed electrical current would be the “1” state.

On the other hand, if the floating gate 42 is negatively charged, the vertical channel region portion 72a is either weakly turned on or is entirely shut off. Even when the control gate 56b and the drain region 60 are raised to their read potentials, little or no current will flow through vertical channel region portion 72a. In this case, either the current is very small compared to that of the “1” state or there is no current at all. In this manner, the memory cell is sensed to be programmed at the “0” state. Ground potential is applied to the source/drain regions 46/60 and control gates 56b for non-selected columns and rows so only the selected memory cell is read.

The memory cell array includes peripheral circuitry including conventional row address decoding circuitry, column address decoding circuitry, sense amplifier circuitry, output buffer circuitry and input buffer circuitry, which are well known in the art.

The present invention provides a memory cell array with reduced size and superior program, read and erase efficiencies. Memory cell size is reduced significantly because the source regions 46 are buried inside the substrate 10, and are self-aligned to the second trenches 36, where space is not wasted due to limitations in the lithography generation, contact alignment and contact integrity. Each floating gate 42 has a lower portion disposed in second trench 36 formed in the substrate for receiving the tunneling electrons during the program operation and for turning on the vertical channel region portion 72a during the read operation. Each floating gate 42 also has an upper portion terminating in a corner edge 42a facing the notch portion 80 of the erase gate 56a for Fowler Nordheim tunneling thereto during the erase operation. Erase efficiency is enhanced by notch 80 of erase gate 56a that wraps around the corner edge 42a.

Also with the present invention, having source region 46 and drain region 60 separated vertically as well as horizontally allows for easier optimization of reliability parameters without affecting cell size. Further, by providing an erase gate 56a that is separate from the control gate 56b, the control gate need only be a low voltage device. This means that high voltage drive circuitry need not be coupled to control gates 56b, control gate 56b can be separated further from floating gate 42 for reduced capacitive coupling there between, and that the oxide layer 54 insulating the control gate 56b from the substrate 10 can be thinner given the lack of high voltage operation of the control gate 56b. Lastly, the memory cells can be formed using just two poly deposition steps, the first for forming the floating gates and the second for forming the control and erase gates.

It is to be understood that the present invention is not limited to the embodiment(s) described above and illustrated herein, but encompasses any and all variations falling within the scope of the appended claims. For example, trenches 20/36 can end up having any shape that extends into the substrate, with sidewalls that are or are not oriented vertically, not just the elongated rectangular shape shown in the figures. Also, although the foregoing method describes the use of appropriately doped polysilicon as the conductive material used to form the memory cells, it should be clear to those having ordinary skill in the art that in the context of this disclosure and the appended claims, “polysilicon” refers to any appropriate conductive material that can be used to form the elements of non-volatile memory cells. In addition, any appropriate insulator can be used in place of silicon dioxide or silicon nitride. Moreover, any appropriate material having etch properties that differ from that of silicon dioxide (or any insulator) and from polysilicon (or any conductor) can be used. Further, as is apparent from the claims, not all method steps need be performed in the exact order illustrated or claimed, but rather in any order that allows the proper formation of the memory cell of the present invention. Additionally, the above described invention is shown to be formed in a substrate which is shown to be uniformly doped, but it is well known and contemplated by the present invention that memory cell elements can be formed in well regions of the substrate, which are regions that are doped to have a different conductivity type compared to other portions of the substrate. Single layers of insulating or conductive material could be formed as multiple layers of such materials, and vice versa. The top surfaces of floating gates 42 may extend above, or can be recessed below, the substrate surface. Lastly, while notches 80 surrounding floating gate edges 42a are preferable, they are not necessarily mandatory, as it is possible to implement erase gate 56a without notches 80 (e.g. where the lower portion of erase gate 56a is simply laterally adjacent to or vertically adjacent to (and insulated from) floating gate 42.

References to the present invention herein are not intended to limit the scope of any claim or claim term, but instead merely make reference to one or more features that may be covered by one or more of the claims. Materials, processes and numerical examples described above are exemplary only, and should not be deemed to limit the claims. It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between). For example, forming an element “over a substrate” can include forming the element directly on the substrate with no intermediate materials/elements there between, as well as forming the element indirectly on the substrate with one or more intermediate materials/elements there between.

1. A pair of memory cells, comprising:
a substrate of semiconductor material having a first conductivity type and a surface;
a trench formed into the surface of the substrate and including a pair of opposing sidewalls;
a first region formed in the substrate under the trench;
a pair of second regions formed in the substrate, with a pair of channel regions each in the substrate between the first region and one of the second regions, wherein the first and second regions have a second conductivity type, and wherein each of the channel regions includes a first portion that extends substantially along one of the opposing trench sidewalls and a second portion that extends substantially along the substrate surface;
a pair of electrically conductive floating gates each at least partially disposed in the trench adjacent to and insulated from one of the channel region first portions for controlling a conductivity of the one channel region first portion;
an electrically conductive erase gate having a lower portion disposed in the trench and disposed adjacent to and insulated from the floating gates; and
a pair of electrically conductive control gates each disposed over and insulated from one of the channel region second portions for controlling a conductivity of the one channel region second portion;
wherein any portion of the trench between the pair of floating gates is free of electrically conductive elements except for the erase gate lower portion.

2. The array of claim 1, wherein there is no vertical overlap between the pair of control gates and the pair of floating gates.

3. The array of claim 1, wherein the erase gate is disposed adjacent to the floating gates and insulated there from with insulation material having a thickness that permits Fowler-Nordheim tunneling.

4. The array of claim 1, wherein the erase gate includes a pair of notches and each of the floating gates includes an edge that directly faces and is insulated from one of the pair of notches.

5. The array of claim 4, wherein the erase gate includes an upper portion having a first width, and wherein the erase gate lower portion has a second width that is less than the first width.

6. The array of claim 5, wherein the pair of notches are disposed where the first and second portions of the erase gate meet.

7. A method of forming a pair of memory cells, comprising:
forming a trench into a surface of the semiconductor substrate of first conductivity type, wherein the trench has a pair of opposing sidewalls;
forming a first region in the substrate and under the trench;
forming a pair of second regions in the substrate, with a pair of channel regions each defined in the substrate between the first region and one of the second regions, wherein the first and second regions have a second conductivity type, and wherein each of the channel regions includes a first portion that extends substantially along one of the opposing trench sidewalls and a second portion that extends substantially along the surface of the substrate;
forming a pair of electrically conductive floating gates each at least partially disposed in the trench adjacent to and insulated from one of the channel region first portions for controlling a conductivity of the one channel region first portion;
forming an electrically conductive erase gate having a lower portion disposed in the trench and disposed adjacent to and insulated from the floating gates; and
forming a pair of electrically conductive control gates each disposed over and insulated from one of the channel region second portions for controlling a conductivity of the one channel region second portion;
wherein any portion of the trench between the pair of floating gates is free of electrically conductive elements except for the erase gate lower portion.

8. The method of claim 7, wherein there is no vertical overlap between the pair of control gates and the pair of floating gates.

9. The method of claim 7, wherein the erase gate includes a pair of notches and each of the floating gates includes an edge that directly faces and is insulated from one of the pair of notches.

10. The method of claim 9, wherein the formation of the erase gate comprises:
forming an upper portion of the erase gate having a first width; and
forming the lower portion of the erase gate having a second width that is less than the first width.

11. The method of claim 10, wherein the pair of notches are disposed where the first and second portions of the erase gate meet.

12. The method of claim 7, further comprising:
forming a sacrificial layer of oxide on the opposing sidewalls of the trench; and
removing the sacrificial layer of oxide.

13. The method of claim 7, wherein the formation of the floating gates comprises:
forming conductive material in the trench;
forming a pair of opposing spacers of insulation material on the conductive material such that a portion of the conductive material is exposed between the pair of opposing spacers; and
removing the exposed portion of the conductive material.

14. The method of claim 13, wherein the removing of the exposed portion of the conductive material comprises an anisotropic etch.

15. The method of claim 13, wherein the formation of the erase and control gates comprises:
forming a layer of conductive material having a first portion disposed between the opposing spacers, and second and third portions disposed over the substrate surface with the opposing spacers disposed there between.

16. The method of claim 13, further comprising:
performing an etch that reduces a thickness of the opposing spacers and increases a width of a space between the opposing spacers.

17. The method of claim 16, wherein the forming of the erase gate comprises:
forming an upper portion of the erase gate in the space between the opposing spacers after the etch.

18. (canceled)
